(19) United States
(12) Patent Application Publication
(10) Pub. No.: US 2026/0324251 A1
(43) Pub. Date: Oct. 15, 2026

(54) Display Device, Electronic Device And Method For Fabricating The Same

(71) Applicant: Samsung Display Co, Ltd., Yongin-si (KR)

(72) Inventors: Tae Sang Park, Yongin-si (KR); Tae Sung Kim, Yongin-si (KR); Kyong Choi Lee, Yongin-si (KR); Yu Gwang Jeong, Yongin-si (KR); Hyun Min Cho, Yongin-si (KR)

(73) Assignee: Samsung Display Co, Ltd., Yongin-si (KR)

(21) Appl. No.: 19/454,624

(22) Filed: Jan. 21, 2026

(30) Foreign Application Priority Data
Apr. 10, 2025 (KR) 10-2025-0046604

(51) Int. Cl. H10K 59/80; H10K 59/12; H10K 59/122; H10K 59/123; H10K 71/60; H10K 102/00; H10K 102/10

(52) U.S. Cl. CPC H10K 59/80517; H10K 59/1201; H10K 59/122; H10K 59/123; H10K 59/80516; H10K 71/60; H10K 2102/103; H10K 2102/331

(57) ABSTRACT

The disclosure provides a display device. The display device includes a substrate including an emission area and a non-emission area, a bank structure located on the substrate and having an overhang structure, an anode contact hole overlapping the emission area and penetrating through the bank structure, an element insulating layer located on the bank structure and covering a side surface of the bank structure so as to overlap the anode contact hole, an anode auxiliary electrode located on the element insulating layer, an anode electrode located on the element insulating layer and the anode auxiliary electrode, and an anode planarization layer located between the anode auxiliary electrode and the anode electrode. The anode planarization layer is located in the anode contact hole, and includes silver and a plurality of voids spaced apart from each other, thereby reducing electrical resistance of the display device.

### CROSS-REFERENCE TO RELATED APPLICATION

This application claims priority to and the benefit of Korean Patent Application No. 10-2025-0046604, filed on Apr. 10, 2025, the disclosure of which is incorporated by reference herein in its entirety.

### TECHNICAL FIELD

The present disclosure relates to a display device, an electronic device that uses the display device, and a method for fabricating such a device. More particularly, the present disclosure related to a display device with improved reliability, an electronic device that includes such a display device, and a method of manufacturing such a device.

### BACKGROUND

As the information society develops, the demand for display devices for displaying images has increased and diversified. For example, display devices have been applied to various electronic devices such as smartphones, digital cameras, laptop computers, navigation devices, and smart televisions. The display devices may be flat panel display devices such as liquid crystal display devices, field emission display devices, or organic light emitting display devices. Among such flat panel display devices, a light emitting display device may display an image without a backlight unit providing light to a display panel because each of pixels of the display panel includes light emitting elements that may emit light by themselves. However, contact defects of the anode electrode for such flat panel display devices may reduce the image quality.

Accordingly, there is a need for display devices with improved image quality and reliability.

### BRIEF SUMMARY

The disclosure is intended to solve problems including improving image quality and reliability. The present disclosure describes a display device capable of providing a high-resolution image, an electronic device that includes the contemplated display device, and a method for fabricating the same.

Aspects of the present disclosure also provide a display device in which electrical resistance of an anode electrode is reduced thereby reducing a contact defect of the anode electrode.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

In some embodiments, a display device includes a substrate including an emission area and a non-emission area; a bank structure located on the substrate and having an overhang structure; an anode contact hole overlapping the emission area and penetrating through the bank structure; an element insulating layer located on the bank structure and covering a side surface of the bank structure so as to overlap the anode contact hole; an anode auxiliary electrode located on the element insulating layer; an anode electrode located on the element insulating layer and the anode auxiliary electrode; and an anode planarization layer located between the anode auxiliary electrode and the anode electrode, located in the anode contact hole, and including silver, wherein the anode planarization layer includes a plurality of voids spaced apart from each other.

In some embodiments, the anode planarization layer further includes an agglomeration which is located between the voids and in which a plurality of silver particles are agglomerated.

In some embodiments, the silver particle included in the anode planarization layer has a size of 1 nanometer or more and 100 nanometers or less.

In some embodiments, the anode planarization layer includes an upper surface facing the anode electrode, and the upper surface of the anode planarization layer has a surface roughness of 10 nanometers or less.

In some embodiments, the anode auxiliary electrode includes an upper surface facing the anode electrode, and the anode electrode includes a portion in contact with the upper surface of the anode planarization layer and a portion in contact with the upper surface of the anode auxiliary electrode.

In some embodiments, the anode electrode includes a first layer and a third layer each including transparent conductive oxide and a second layer including silver, the anode planarization layer may be in contact with the first layer, and in a portion overlapping the anode contact hole, the anode auxiliary electrode, the anode planarization layer, and the first layer, the second layer, and the third layer of the anode electrode are sequentially stacked.

In some embodiments, a stacked structure of the anode auxiliary electrode, the anode planarization layer, and the first layer, the second layer, and the third layer of the anode electrode comprises indium tin oxide (ITO)/Ag/ITO/Ag/ITO.

In some embodiments, in plan view, the voids are located between a plurality of the agglomerations.

In some embodiments, the bank structure includes a first bank layer; a second bank layer located on the first bank layer; and a third bank layer having a tip protruding more than a first side surface of the second bank layer toward the non-emission area, and in a portion overlapping the anode contact hole, the anode planarization layer penetrates through the first bank layer, the second bank layer, and the third bank layer.

In some embodiments, the display device further comprises a pixel defining layer covering an edge of the anode electrode, in contact with the element insulating layer, and defining an emission opening; a first light emitting layer located on the anode electrode and entirely covering the pixel defining layer; and a cathode electrode located on the first light emitting layer, wherein the cathode electrode is in contact with the tip of the third bank layer.

In some embodiments, the display device further comprises a connection electrode located between the substrate and the bank structure, wherein the anode auxiliary electrode is in contact with the connection electrode, and the anode electrode is electrically connected to the connection electrode by the anode planarization layer and the anode auxiliary electrode.

According to some embodiments, a method is provided for fabricating a display device, the method comprising blocks for: forming an anode contact hole penetrating through a bank structure and forming an anode auxiliary electrode on the bank structure; forming an anode planarization layer on the anode auxiliary electrode, the anode planarization layer including silver particles; and forming an anode electrode on the anode planarization layer and forming a pixel defining layer.

In some embodiments, in the forming of the anode planarization layer on the anode auxiliary electrode, the silver particle has a size of 1 nanometer or more and 100 nanometers or less, and a process of forming the anode planarization layer includes a process of coating a solution in which the silver particles are dispersed in a solvent and a process of removing the solvent.

In some embodiments, the process of forming the anode planarization layer includes a plasma treatment process including a fluorine-based gas.

In some embodiments, the bank structure includes a reverse tapered shape, the bank structure includes a first bank layer, a second bank layer, and a third bank layer, the second bank layer includes aluminum, and the third bank layer includes titanium.

According to some embodiments of the disclosure, an electronic device comprises at least one display device including a substrate including an emission area and a non-emission area; and at least one of a display module, a processor, a memory, and a power module connected to the at least one display device, wherein the at least one display device includes: a bank structure located on the substrate and having an overhang structure; an anode contact hole overlapping the emission area and penetrating through the bank structure; an element insulating layer located on the bank structure and covering a side surface of the bank structure so as to overlap the anode contact hole; an anode auxiliary electrode located on the element insulating layer; an anode electrode located on the element insulating layer and the anode auxiliary electrode; and an anode planarization layer located between the anode auxiliary electrode and the anode electrode, located in the anode contact hole, and including silver, and the anode planarization layer includes a plurality of voids spaced apart from each other.

In some embodiments, in a portion overlapping the anode contact hole, the anode auxiliary electrode, the anode planarization layer, and the first layer, the second layer, and the third layer of the anode electrode are sequentially stacked.

In some embodiments, an electronic device that includes the display device of the present disclosure is provided. In some embodiments a method for fabricating such a device is provided. In some embodiments, the display device includes light emitting elements located on a bank structure and anode contact holes penetrating through the bank structure, and accordingly, provides a high-resolution image.

In addition, with the display device according to some embodiments, the electronic device using the same, and the method for fabricating the same, the display device includes an anode planarization layer located in the anode contact hole and including silver (Ag) particles having a nano size, and accordingly, electrical resistance of an anode electrode is reduced and a contact defect of the anode electrode is resolved.

Benefits of the display device of the present disclosure are not limited to the aforementioned and various other effects are described in the detailed description below.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to an embodiment of the present disclosure;

FIG. 2 is a cross-sectional view illustrating the display device according to an embodiment of the present disclosure;

FIG. 3 is a plan view illustrating a display layer of the display device according to an embodiment of the present disclosure;

FIG. 4 is a layout diagram illustrating an arrangement of a plurality of pixels disposed in a display area of FIG. 3;

FIG. 5 is a cross-sectional view illustrating an example of the display layer taken along line A1-A1′ of FIG. 4;

FIG. 6 is an enlarged cross-sectional view of a display element layer overlapping a first emission area in FIG. 5;

FIG. 7 is an enlarged cross-sectional view of area ‘P’ in FIG. 6;

FIG. 8 is an enlarged field emission scanning electron microscope (FE-SEM) plane image of an upper surface of an anode planarization layer in FIG. 6;

FIG. 9 is a flowchart illustrating a method for fabricating a portion of the display element layer in FIG. 5 in accordance with the present disclosure;

FIGS. 10 and 11 are cross-sectional views for describing the forming of the anode contact holes penetrating through the bank structure and the forming of the anode auxiliary electrode on the bank structure according to FIG. 9;

FIGS. 12 to 15 are cross-sectional views for describing the forming of the anode planarization layers on the anode auxiliary electrode according to FIG. 9;

FIGS. 16 to 20 are cross-sectional views for describing the forming the anode electrodes on the anode planarization layers and the forming of the pixel defining layer according to FIG. 9;

FIG. 21 is a block diagram of an electronic device according to an embodiment of the present disclosure; and

FIG. 22 is schematic views of electronic devices according to various embodiments of the present disclosure.

### DETAILED DESCRIPTION OF THE EMBODIMENTS

While specific embodiments are shown in the drawings and described in detail herein below, the present disclosure may be modified in a variety of ways and realized in many different forms. Accordingly, it will be appreciated that the present disclosure is not limited to the specific disclosed forms, and should be construed to include all modifications, equivalents, or replacements included within the spirit and scope of the present disclosure.

In addition, spatially relative terms, such as “below”, “lower”, “above”, “upper” and the like, may be used herein for ease of description to describe one element or feature's relationship to another element or feature as shown in the figures.

It is also to be understood that when a layer is referred to as being “on” another layer or substrate, it may be directly on the other layer or substrate, or one or more intervening layers may also be present. The same reference numbers indicate the same components throughout the specification.

It is to be understood that, although the terms “first,” “second,” etc. may be used herein to describe various elements, these elements should not be limited by these terms. These terms are used to distinguish one element from another element. For instance, a first element discussed below could be termed a second element without departing from the teachings of the present disclosure. Similarly, the second element could also be termed a first element.

In the examples below, the terms first, second, etc. are not used in a limiting sense but are used for the purpose of distinguishing one component from another. As such, in the present disclosure, it will be understood that when a first element (or area, layer, or portion) is referred to as being “on”, “connected to” or “coupled to” a second element or layer, the first element can be directly on, connected or coupled to the second element or layer or intervening elements or layers may be present and disposed in between the first and second elements.

Unless otherwise defined, all terms (including technical and scientific terms) used herein have the same meaning as commonly understood by one of ordinary skill in the art to which the inventive concept pertains. It is also to be understood that terms defined in commonly used dictionaries should be interpreted as having meanings consistent with the meanings in the context of the related art, and are expressly defined herein unless they are interpreted in an ideal or overly formal sense.

Hereinafter, embodiments of the present disclosure will be described in detail with reference to the accompanying drawings. When describing with reference to the drawings, identical or corresponding components are given the same drawing reference numerals and redundant descriptions thereof are omitted.

In the examples below, singular expressions include plural expressions unless the context clearly indicates otherwise.

In the examples below, terms such as “include” or “have” mean that a feature or component described in the specification is present, and do not exclude in advance the possibility that one or more other features or components may be added.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

In the following examples, when a part such as a film, region, component, etc. is said to be on or above another part, it includes not only the case where it is directly on top of the other part, but also the case where another film, region, component, etc. is interposed in between.

In the drawings, sizes of components may be exaggerated or reduced for convenience of explanation. For example, a size and thickness of each component shown in the drawing are arbitrarily shown for convenience of explanation, and thus the present implementation of the teachings of the present disclosure are not necessarily limited to what is shown.

Additionally, the terms “about,” “generally,” and “substantially” are intended to mean, and a person of ordinary skill would understand them to mean that slight deviations from absolute are included within the scope of the term so modified.

In some embodiments, where the implementation is otherwise feasible, specific process sequences may be performed in a different order than described. For example, two processes described sequentially may be performed substantially simultaneously, or may proceed in the reverse order from that described.

In this specification, “A and/or B” refers to either A, B, or both A and B. And, “at least one of A and B” indicates the case where it is A, or B, or both A and B.

In the following examples, when it is said that a film, region, component, etc. are connected, it includes a case where the films, regions, or components are directly connected, and/or a case where other films, regions, or components are interposed between the films, regions, or components and are indirectly connected. For example, when it is said in this specification that a film, region, component, etc. are electrically connected, it refers to a case where the film, region, component, etc. are directly electrically connected, and/or a case where another film, region, component, etc. is interposed between them and is indirectly electrically connected.

The x-axis, y-axis, and z-axis are not limited to the three axes on the orthogonal coordinate system and may be interpreted in a broad sense that includes them. For example, the x-axis, y-axis, and z-axis may be orthogonal to each other, but they may also refer to different directions that are not orthogonal to each other.

A display device according to an embodiment may be included in various electronic devices. In some aspect, an electronic device according to an embodiment includes the display device described above, and may further include a module or device having additional functions in addition to the display device.

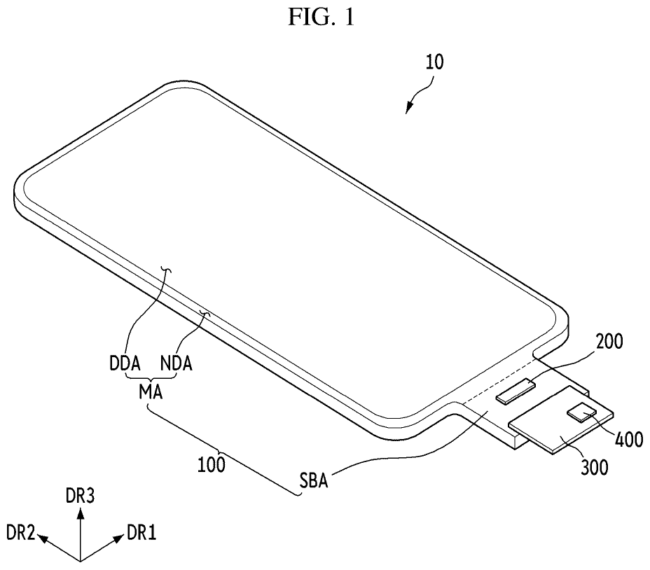

FIG. 1 is a perspective view illustrating a display device according to an embodiment.

Referring to FIG. 1, a display device 10 may be applied to portable electronic devices such as mobile phones, smartphones, tablet personal computers (PCs), mobile communication terminals, electronic notebooks, electronic books, portable multimedia players (PMPs), navigation devices, and ultra mobile PCs (UMPCs). As an example, the display device 10 may be applied as a display unit of televisions, laptop computers, monitors, billboards, or the Internet of Things (IOTs). As another example, the display device 10 may be applied to wearable devices such as smart watches, watch phones, glasses-type displays, and head mounted displays (HMDs).

The display device 10 may have a shape similar to a rectangular shape in plan view. For example, the display device 10 may have a shape similar to a rectangular shape, in plan view, having short sides in a first direction DR1 and long sides in a second direction DR2. A corner where the short side in the first direction DR1 and the long side in the second direction DR2 meet may be rounded with a selected curvature or right-angled. The shape of the display device 10 in plan view is not limited to the rectangular shape, and may be a shape similar to other polygonal shapes, a circular shape, or an elliptical shape.

The display device 10 may include a display panel 100, a display driver 200, a circuit board 300, and a touch driver 400.

The display panel 100 may include a main area MA and a sub-area SBA. The main area MA may include a display area DDA including pixels displaying an image and a non-display area NDA located around the display area DDA.

The display area DDA may emit light from a plurality of emission areas or a plurality of openings to be described later. For example, the display panel 100 may include pixel circuits including switching elements, an element insulating layer defining the emission areas or the openings, and self-light emitting elements. For example, the self-light emitting element may include at least one of an organic light emitting diode (LED) including an organic light emitting layer, a quantum dot LED including a quantum dot light emitting layer, an inorganic LED including an inorganic semiconductor, and a micro LED, but is not limited thereto. It has been illustrated in the drawings that the self-light emitting element is an organic light emitting diode.

The non-display area NDA may be an area outside the display area DDA. The non-display area NDA may be defined as an edge area of the main area MA of the display panel 100.

The sub-area SBA may be an area extending from one side of the main area MA. The sub-area SBA may include a flexible material that may be bent, folded, and rolled. For example, when the sub-area SBA is bent, the sub-area SBA may overlap the main area MA in a thickness direction (e.g., a third direction DR3). The sub-area SBA may include the display driver 200 and pad portions connected to the circuit board 300. In another embodiment, the sub-area SBA may be omitted, and the display driver 200 and the pad portions may be located in the non-display area NDA.

The display driver 200 may output signals and voltages for driving the display panel 100. The display driver 200 may be formed as an integrated circuit (IC) and mounted on the display panel 100 in a chip on glass (COG) manner, a chip on plastic (COP) manner, or an ultrasonic bonding manner. As an example, the display driver 200 may be located in the sub-area SBA, and may overlap the main area MA in the thickness direction by bending of the sub-area SBA. As another example, the display driver 200 may be mounted on the circuit board 300.

The circuit board 300 may be attached onto the pad portions of the display panel 100 using an anisotropic conductive film (ACF). The circuit board 300 may be a flexible printed circuit board, a printed circuit board, or a flexible film such as a chip on film.

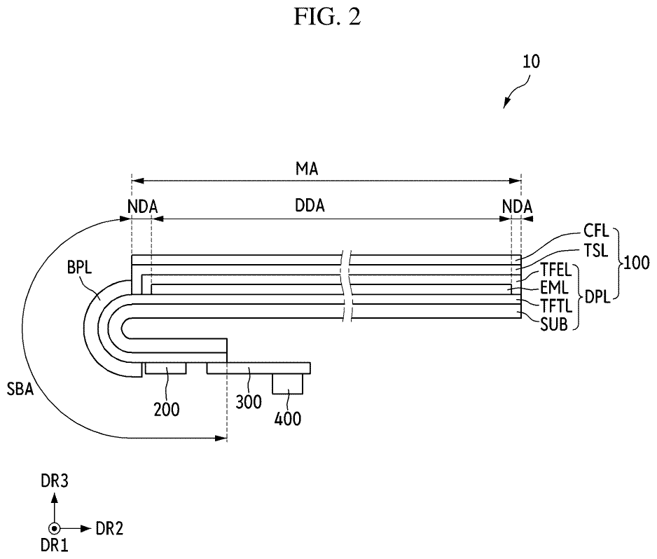

The touch driver 400 may be mounted on the circuit board 300. The touch driver 400 may be connected to a touch sensor layer TSL (see FIG. 2) for sensing and driving a touch.

FIG. 2 is a cross-sectional view illustrating the display device according to an embodiment.

Referring to FIG. 2, the display panel 100 may include a display layer DPL, a touch sensor layer TSL, and a color filter layer CFL. The display layer DPL may include a substrate SUB, a transistor layer TFTL, a display element layer EML, and a thin film encapsulation layer TFEL.

The substrate SUB may be a base substrate or a base member. The substrate SUB may be a flexible substrate that may be bent, folded, and rolled. For example, the substrate SUB may include a polymer resin such as polyimide (PI), but is not limited thereto. In another embodiment, the substrate SUB may include a glass material or a metal material.

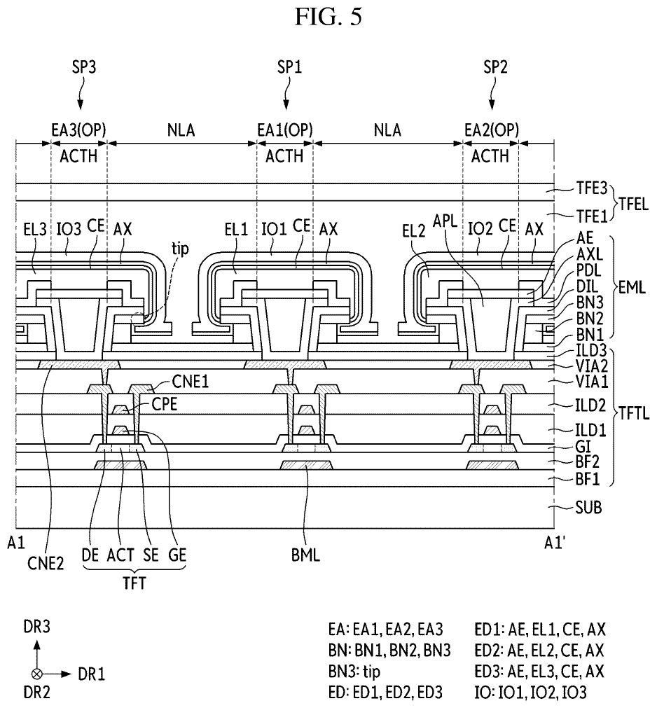

The transistor layer TFTL may be located on the substrate SUB. The transistor layer TFTL may be located in a portion overlapping the display area DDA, the non-display area NDA, and the sub-area SBA. The transistor layer TFTL may include a plurality of transistors TFT (see FIG. 5).

The display element layer EML may be located on the transistor layer TFTL. The display element layer EML may be located in a portion overlapping the display area DDA. The display element layer EML may include at least one of an organic light emitting diode (LED) including an organic light emitting layer, a quantum dot LED including a quantum dot light emitting layer, an inorganic LED including an inorganic semiconductor, and a micro LED, but is not limited thereto.

The thin film encapsulation layer TFEL may be located on the display element layer EML. The thin film encapsulation layer TFEL may be located in a portion overlapping the display area DDA and the non-display area NDA. The thin film encapsulation layer TFEL may cover an upper surface and side surfaces of the display element layer EML, and may protect the display element layer EML from external oxygen and moisture. The thin film encapsulation layer TFEL may include at least one inorganic film and at least one organic film for encapsulating the display element layer EML. The thin film encapsulation layer TFEL may be omitted according to embodiments.

The touch sensor layer TSL may be located on the thin film encapsulation layer TFEL. The touch sensor layer TSL may be located in a portion overlapping the display area DDA and the non-display area NDA. The touch sensor layer TSL may sense a user's touch in a mutual capacitance manner or a self-capacitance manner. The touch sensor layer TSL may be omitted according to embodiments.

The color filter layer CFL may be located on the touch sensor layer TSL. The color filter layer CFL may be located in a portion overlapping the display area DDA and the non-display area NDA. The color filter layer CFL may absorb some of light introduced from the outside of the display device 10 to reduce reflected light by external light. Accordingly, the color filter layer CFL may prevent distortion of colors due to external light reflection.

Since the color filter layer CFL is directly disposed on the touch sensor layer TSL, the display device 10 may not require a separate substrate for the color filter layer CFL. Accordingly, a thickness of the display device 10 may be relatively small. The color filter layer CFL may also be omitted according to embodiments.

As illustrated in FIG. 2, a portion of the display panel 100 overlapping the sub-area SBA may be bent. When a portion of the display panel 100 is bent, the display driver 200, the circuit board 300, and the touch driver 400 may overlap the main area MA in the third direction DR3.

When a portion of the display panel 100 is bent, a bending protection layer BPL may protect an underlying structure overlapping the sub-area SBA from bending stress.

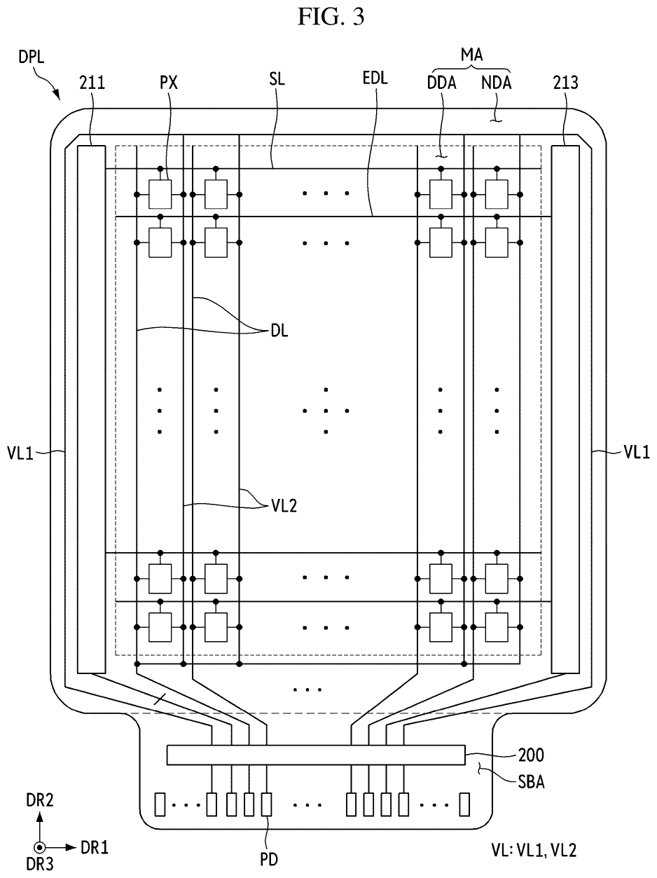

FIG. 3 is a plan view illustrating a display layer of the display device according to an embodiment.

Referring to FIG. 3, the display layer DPL may include a plurality of pixels PX located in a portion overlapping the display area DDA and a plurality of power lines VL, a plurality of scan lines SL, a plurality of emission control lines EDL, and a plurality of data lines DL that are connected to the plurality of pixels PX.

The plurality of scan lines SL may extend in the first direction DR1, and may be spaced apart from each other in the second direction DR2 crossing the first direction DR1. The scan lines SL may be arranged along the second direction DR2. The scan lines SL may sequentially supply scan signals to the plurality of pixels PX.

The emission control lines EDL may extend in the first direction DR1, and may be spaced apart from each other in the second direction DR2. The emission control lines EDL may be arranged along the second direction DR2. The emission control lines EDL may sequentially supply emission signals to the plurality of pixels PX.

The data lines DL may extend in the second direction DR2, and may be spaced apart from each other in the first direction DR1. The data lines DTL may be arranged along the first direction DR1. The data lines DL may supply data voltages to the plurality of pixels PX. The data voltage may determine luminance of each of the plurality of pixels PX.

The power line VL may include a main power line VL1 and sub-power lines VL2. At least one of a first source voltage (high potential voltage) or a second source voltage (low potential voltage) may be transferred to the sub-power supply lines VL2 through the main power supply line VL1 overlapping the non-display area NDA. Hereinafter, the main power supply line VL1 and the sub-power supply line VL2 may be collectively referred to as the power line VL.

The non-display areas NDA may surround the display area DDA. The non-display area NDA may include a scan driver 211 and an emission control driver 213.

The scan driver 211 may be disposed outside one side of the display area DDA or on one side of the non-display area NDA. The scan driver 211 may include a plurality of driving transistors generating gate signals based on a gate control signal.

The emission control driver 213 may be disposed outside the other side of the display area DDA or on the other side of the non-display area NDA. The emission control driver 213 may include a plurality of emission control transistors generating emission signals based on an emission control signal.

The display layer DPL included in an embodiment may include the display driver 200 and a plurality of pad electrodes PD in a portion overlapping the sub-area SBA. The plurality of pad electrodes PD may be spaced apart from each other in the first direction DR1, and the respective pad electrodes PD may be connected to respective different lines.

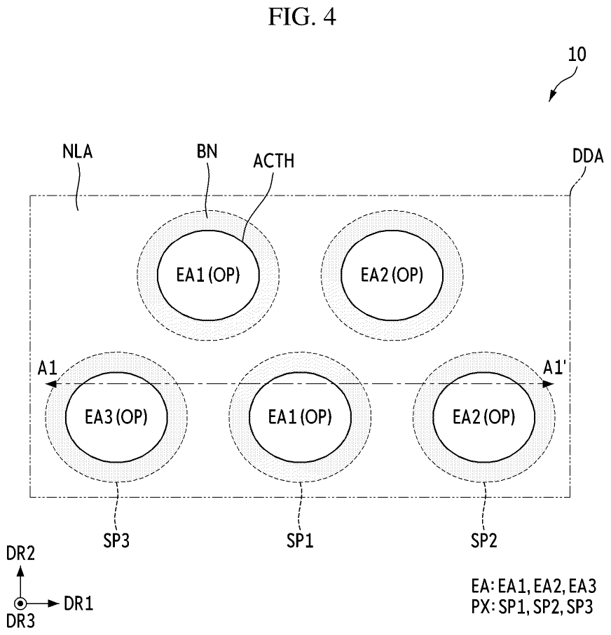

FIG. 4 is a layout diagram illustrating an arrangement of a plurality of pixels disposed in a display area of FIG. 3.

Referring to FIG. 4, the pixel PX according to an embodiment may include a first sub-pixel SP1, a second sub-pixel SP2, and a third sub-pixel SP3 located in a portion overlapping the display area DDA. The first sub-pixel SP1, the second sub-pixel SP2, and the third sub-pixel SP3 may be spaced apart from each other.

The pixel PX may include an emission area EA. The emission area EA may be a portion from which light is emitted. As an example, the first sub-pixel SP1 may include a first emission area EA1, the second sub-pixel SP2 may include a second emission area EA2, and the third sub-pixel SP3 may include a third emission area EA3.

In an embodiment, the first emission area EA1, the second emission area EA2, and the third emission area EA3 may emit light of different colors. As an example, the first emission area EA1 may emit red light, the second emission area EA2 may emit green light, and the third emission area EA3 may emit blue light. However, the present disclosure is not limited thereto, and according to embodiments, the first emission area EA1, the second emission area EA2, and the third emission area EA3 may also emit light of the same color.

In an embodiment, the emission area EA may be defined by an opening OP. The opening OP may be defined by a pixel defining layer PDL (see FIG. 5) to be described later.

In plan view, an anode contact hole ACTH may be located in a portion overlapping the emission area EA. In other words, in plan view, the anode contact hole ACTH may be located in a portion overlapping the opening OP.

The display device 10 according to an embodiment may include a non-emission area NLA in a portion overlapping the display area DDA. The non-emission area NLA may surround each of the first emission area EA1, the second emission area EA2, and the third emission area EA3. The non-emission area NLA may prevent colors of light emitted from the first emission area EA1, the second emission area EA2, and the third emission area EA3 from being mixed with each other.

A bank structure BN may be located in a portion overlapping the non-emission area NLA to define openings in which light-emitting material is deposited, thereby serving as a pixel definition layer. The bank structure BN may surround the opening OP or the anode contact hole ACTH. The bank structure BN illustrated in FIG. 4 may refer to a second bank layer BN2 and a third bank layer BN3 of FIG. 5.

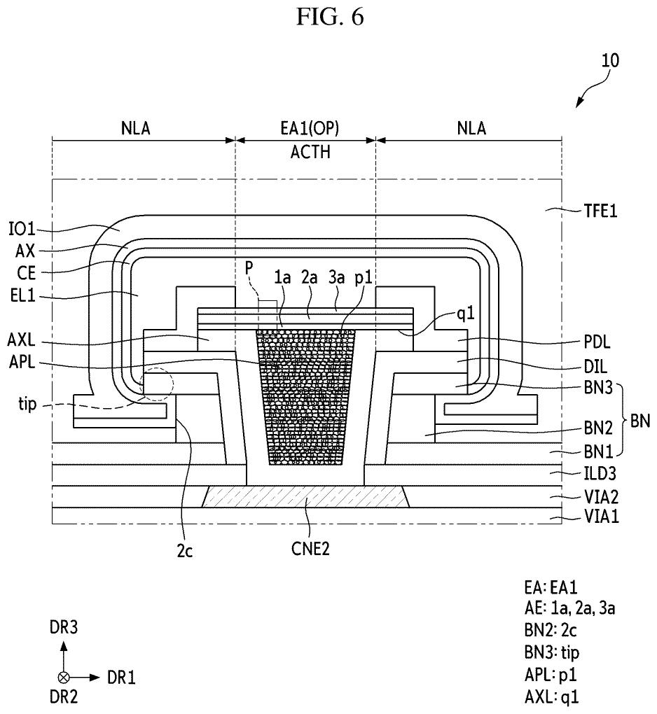

FIG. 5 is a cross-sectional view illustrating an example of the display layer taken along line A1-A1′ of FIG. 4, and FIG. 6 is an enlarged cross-sectional view of a display element layer overlapping a first emission area in FIG. 5. A cross-sectional structure of the first sub-pixel SP1, the second sub-pixel SP2, and the third sub-pixel SP3 in a portion overlapping the display area DDA of the display device 10 has been illustrated in FIG. 5.

Referring to FIGS. 5 and 6, the transistor layer TFTL may be disposed on the substrate SUB. The transistor layer TFTL may include a first buffer layer BF1, bottom metal layers BML, a second buffer layer BF2, transistors TFT, a gate insulating layer GI, a first insulating layer ILD1, capacitor electrodes CPE, a second insulating layer ILD2, first connection electrodes CNE1, a first via layer VIA1, second connection electrodes CNE2, a second via layer VIA2, and a third insulating layer ILD3.

The first buffer layer BF1 may be located on the substrate SUB. The first buffer layer BF1 may include an inorganic film capable of preventing permeation of air or moisture. For example, the first buffer layer BF1 may include a plurality of inorganic films that are alternately stacked.

The bottom metal layers BML may be located on the first buffer layer BF1. The bottom metal layer BML may include a conductive metal. As an example, the bottom metal layer BML may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The second buffer layer BF2 may cover the first buffer layer BF1 and the bottom metal layers BML. The second buffer layer BF2 may include an inorganic film capable of preventing permeation of air or moisture. For example, the second buffer layer BF2 may include a plurality of inorganic films that are alternately stacked.

The transistor TFT may be disposed on the second buffer layer BF2, and may constitute a pixel circuit. As an example, the transistor TFT may be a driving transistor or a switching transistor of the pixel circuit.

The transistor TFT may include an active layer ACT, a source electrode SE, a drain electrode DE, and a gate electrode GE.

The active layer ACT may be located on the second buffer layer BF2. The active layer ACT may overlap the gate electrode GE in the third direction DR3, and may be insulated from the gate electrode GE by the gate insulating layer GI. The source electrode SE and the drain electrode DE may be formed by making portions of the active layer ACT conductors.

The gate insulating layer GI may be located on the active layer ACT. The gate insulating layer GI may cover the active layer ACT and the second buffer layer BF2, and may insulate the active layer ACT and the gate electrode GE from each other. The gate insulating layer GI may include contact holes through which the first connection electrodes CNE1 penetrate.

The gate electrode GE may be located on the gate insulating layer GI. The gate electrode GE may overlap the active layer ACT with the gate insulating layer GI. The gate insulating layer GI may be disposed between the gate electrode GE and the active layer ACT.

The gate electrode GE may include a conductive metal. As an example, the gate electrode GE may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The first insulating layer ILD1 may cover the gate electrode GE and the gate insulating layer GI. The first insulating layer ILD1 may include contact holes through which the first connection electrodes CNE1 penetrate. The contact holes of the first insulating layer ILD1 may be connected to the contact holes of the gate insulating layer GI and contact holes of the second insulating layer ILD2.

The capacitor electrodes CPE may be located on the first insulating layer ILD1. The capacitor electrode CPE may overlap the gate electrode GE in the third direction DR3. The capacitor electrode CPE and the gate electrode GE may form capacitance.

The second insulating layer ILD2 may cover the capacitor electrodes CPE and the first insulating layer ILD1. The second insulating layer ILD2 may include contact holes through which the first connection electrodes CNE1 penetrate. The contact holes of the second insulating layer ILD2 may be connected to the contact holes of the first insulating layer ILD1 and the contact holes of the gate insulating layer GI.

The first connection electrodes CNE1 may be located on the second insulating layer ILD2. The first connection electrode CNE1 may electrically connect the drain electrode DE of the transistor TFT and the second connection electrode CNE2 to each other. The first connection electrode CNE1 may be inserted into the contact holes formed in the first insulating layer ILD1, the second insulating layer ILD2, and the gate insulating layer GI to be in contact with the drain electrode DE of the transistor TFT.

The first via layer VIA1 may be located on the first connection electrode CNE1 and the second insulating layer ILD2. The first via layer VIA1 may planarize an underlying structure. The first via layer VIA1 may include contact holes through which the second connection electrodes CNE2 penetrate.

The first via layer VIA1 may include an organic insulating material. As an example, the first via layer VIA1 may include an acrylic resin, polyimide, polyamide, benzocyclobutene, a phenolic resin, and the like.

The second connection electrodes CNE2 may be located on the first via layer VIA1. The second connection electrode CNE2 may be located in a portion overlapping the emission area EA. The second connection electrodes CNE2 may be inserted into the contact holes formed in the first via layer VIA1 to be in contact with the first connection electrodes CNE1.

The second via layer VIA2 may be located on the first via layer VIA1. The second via layer VIA2 may planarize a step formed by the second connection electrode CNE2.

The second via layer VIA2 may include an organic material. As an example, the second via layer VIA2 may an acrylic resin, a silicone resin, a silicone acrylic resin, an epoxy resin, polyimide, polyamide, benzocyclobutene, a phenolic resin, and the like.

The third insulating layer ILD3 may be located on the second via layer VIA2. The third insulating layer ILD3 may assist in preventing an outgas caused by the organic material of the second via layer VIA2 from permeating into the display element layer EML.

The third insulating layer ILD3 may include an inorganic insulating material. As an example, the third insulating layer ILD3 may include at least one of silicon nitride, silicon oxide, and silicon oxynitride.

The display element layer EML may be disposed on the transistor layer TFTL. The display element layer EML may include a bank structure BN, an element insulating layer DIL, a light emitting element ED, an anode planarization layer APL, and an element inorganic layer IO.

The bank structure BN may be disposed on the third insulating layer ILD3. The bank structure BN may be located in a portion overlapping the non-emission area NLA, and may surround the emission area EA, the opening OP, or/and the anode contact hole ACTH.

The bank structure BN may assist first to third light emitting elements ED1, ED2, and ED3 to be located in portions overlapping the first to third emission areas EA1, EA2, and EA3, respectively, and may assist cathode electrodes CE located in the first to third emission areas EA1, EA2, and EA3 so as to be spaced apart from each other to be electrically connected to each other.

The bank structure BN may include a first bank layer BN1, a second bank layer BN2, and a third bank layer BN3. The first bank layer BN1, the second bank layer BN2, and the third bank layer BN3 may be sequentially stacked in the third direction DR3.

The first bank layer BN1 may be located on the third insulating layer ILD3. The first bank layer BN1 may assist in applying a low potential voltage to the cathode electrode CE.

The first bank layer BN1 may include a conductive metal having etching resistance. As an example, the first bank layer BN1 may include titanium (Ti).

The first bank layer BN1 may be penetrated by the anode contact hole ACTH. In other words, the first bank layer BN1 may surround the anode contact hole ACTH. The first bank layer BN1 may have the form of one conductive pattern surrounding the anode contact hole ACTH.

The second bank layer BN2 may be located on the first bank layer BN1 so as to be in contact with the first bank layer BN1. The second bank layer BN2 may be penetrated by the anode contact hole ACTH. The second bank layer BN2 may surround the anode contact hole ACTH.

The number of second bank layers BN2 may be plural, and the plurality of second bank layers BN2 may be spaced apart from each other in the first direction DR1. In other words, the plurality of second bank layers BN2 may be located in portions overlapping the first to third emission areas EA1, EA2, and EA3, respectively, and the respective second bank layers BN2 may be spaced apart from each other in an island shape.

The second bank layer BN2 may assist the first bank layer BN1 and the third bank layer BN3 to be electrically connected to each other. In other words, the second bank layer BN2 may be electrically connected to the first bank layer BN1 and the third bank layer BN3. Accordingly, the second bank layer BN2 located in a portion overlapping the first emission area EA1, the second bank layer BN2 located in a portion overlapping the second emission area EA2, and the second bank layer BN2 located in a portion overlapping the third emission area EA3 may be electrically connected to each other by the first bank layer BN1.

The second bank layer BN2 may include a metal having high electrical conductivity. As an example, the second bank layer BN2 may include aluminum (Al).

The third bank layer BN3 may be located on the second bank layer BN2 so as to be in contact with the second bank layer BN2. The third bank layer BN3 may be penetrated by the anode contact hole ACTH. The third bank layer BN3 may surround the anode contact hole ACTH.

The number of third bank layer BN3 may be plural, and the plurality of third bank layer BN3 may be spaced apart from each other in the first direction DR1. In other words, the plurality of third bank layer BN3 may be located in portions overlapping the first to third emission areas EA1, EA2, and EA3, respectively, and the respective third bank layer BN3 may be spaced apart from each other in an island shape.

The third bank layer BN3 may include a conductive metal having etching resistance. As an example, the third bank layer BN3 may include titanium (Ti).

In an embodiment, the third bank layer BN3 located in a portion overlapping the first emission area EA1, the third bank layer BN3 located in a portion overlapping the second emission area EA2, and the third bank layer BN3 located in a portion overlapping the third emission area EA3 may be electrically connected to each other through the second bank layer BN2 and the first bank layer BN1. An overlapping description is omitted.

As illustrated in FIG. 6, the second bank layer BN2 may include a side surface 2c facing the non-emission area NLA, and the third bank layer BN3 may include a tip protruding more than the side surface 2c of the second bank layer BN2 in the first direction DR1. Accordingly, the side surface 2c of the second bank layer BN2 and the tip of the third bank layer BN3 may form an undercut. In other words, the bank structure BN may have an overhang structure.

The element insulating layer DIL may be located on the third bank layer BN3. The element insulating layer DIL may cover the third bank layer BN3, and may overlap the tip of the third bank layer BN3 in the third direction DR3.

The element insulating layer DIL may be penetrated by the anode contact hole ACTH in a portion overlapping the emission area EA. In other words, the element insulating layer DIL may surround the anode contact hole ACTH.

The element insulating layer DIL may allow the bank structure BN and an anode electrode AE to be spaced apart and insulated from each other so that the bank structure BN and the anode electrode AE are not in contact with each other. Accordingly, the element insulating layer DIL may entirely cover a side surface of the bank structure BN facing the anode contact hole ACTH. For this reason, the element insulating layer DIL may solve a short-circuit defect of the display device 10 due to the contact between the anode electrode AE and the bank structure BN.

The element insulating layer DIL may include an inorganic insulating material. As an example, the element insulating layer DIL may include at least one of silicon nitride, silicon oxide, and silicon oxynitride.

A pixel defining layer PDL may be located on the element insulating layer DIL. The pixel defining layer PDL may define the opening OP, and may expose the anode electrode AE in a portion overlapping the opening OP. In other words, the pixel defining layer PDL may surround the opening OP, and may cover an edge of the anode electrode AE.

The pixel defining layer PDL may include an inorganic insulating material. As an example, the pixel defining layer PDL may include at least one of silicon nitride, silicon oxide, and silicon oxynitride.

An anode auxiliary electrode AXL may be located on the element insulating layer DIL. The anode auxiliary electrode AXL may be in contact with and cover the element insulating layer DIL, and may extend and be in contact with the second connection electrode CNE2. In other words, the anode auxiliary electrode AXL may entirely cover the element insulating layer DIL and the third insulating layer ILD3 and may extend and be in contact with the second connection electrode CNE2, in a portion overlapping the anode contact hole ACTH. Accordingly, the anode auxiliary electrode AXL may be electrically connected to the second connection electrode CNE2.

The anode auxiliary electrode AXL may cover the element insulating layer DIL, the third insulating layer ILD3, and the second connection electrode CNE2 at a uniform thickness along a profile formed by the element insulating layer DIL, the third insulating layer ILD3, and the second connection electrode CNE2. Accordingly, the anode auxiliary electrode AXL may include a step that is the same as a shape of an underlying structure. The meaning of the uniform thickness described above may include a process error of 10% or less.

The anode auxiliary electrode AXL may include transparent conductive oxide (TCO). As an example, the anode auxiliary electrode AXL may include at least one of indium zinc oxide (IZO) and indium tin oxide (ITO).

The light emitting element ED according to an embodiment may be located on the bank structure BN. The light emitting element ED may overlap the bank structure BN and the element insulating layer DIL in the third direction DR3. In addition, the light emitting element ED may overlap the anode contact hole ACTH in the third direction DR3.

The display device 10 according to an embodiment may be applied to a high-resolution electronic device. Accordingly, a plurality of light emitting elements ED included in the display device 10 may be required to be disposed while securing an appropriate spacing distance within a narrow area. Accordingly, the display device 10 according to an embodiment may include the plurality of light emitting elements ED efficiently disposed within a narrow area by forming the light emitting elements ED to be located on the bank structure BN.

In addition, in the display device 10 according to an embodiment, the bank structure BN includes the tip, and accordingly, a first light emitting element ED1, a second light emitting element ED2, and a third light emitting element ED3 spaced apart from each other may be formed without a separate fine metal mask in a fabricating process. In other words, the light emitting element ED according to an embodiment may be formed by a photo pattern process.

The light emitting element ED may include the first light emitting element ED1 disposed in the first emission area EA1, the second light emitting element ED2 disposed in the second emission area EA2, and the third light emitting element ED3 disposed in the third emission area EA3. The first light emitting element ED1, the second light emitting element ED2, and the third light emitting element ED3 may be spaced apart from each other.

The first light emitting element ED1 may include an anode electrode AE, a first light emitting layer EL1, a cathode electrode CE, and an auxiliary electrode AX, the second light emitting element ED2 may include an anode electrode AE, a second light emitting layer EL2, a cathode electrode CE, and an auxiliary electrode AX, and the third light emitting element ED3 may include an anode electrode AE, a third light emitting layer EL3, a cathode electrode CE, and an auxiliary electrode AX.

The first light emitting element ED1, the second light emitting element ED2, and the third light emitting element ED3 may emit light of different colors. As an example, the first light emitting element ED1 may emit red light, the second light emitting element ED2 may emit green light, and the third light emitting element ED3 may emit blue light. The colors of the light emitted by the first light emitting element ED1, the second light emitting element ED2, and the third light emitting element ED3 may be determined by the first light emitting layer EL1, the second light emitting layer EL2, and the third light emitting layer EL3.

In an embodiment, the anode contact hole ACTH may be located in a portion overlapping the emission area EA. The anode contact hole ACTH may penetrate through the third insulating layer ILD3, the first bank layer BN1, the second bank layer BN2, and the third bank layer BN3.

In the display device 10 according to an embodiment, an area of the anode contact hole ACTH is not formed in a separate space, and is formed to overlap the emission area EA, and thus, a contact area of the anode electrode AE and the emission area EA may be integrated with each other. Accordingly, in the display device 10 according to an embodiment, a plurality of emission areas EA may be efficiently disposed within a narrow area.

The anode electrode AE may be located on the anode auxiliary electrode AXL. The anode electrode AE may be in contact with and electrically connected to the anode auxiliary electrode AXL.

The anode electrodes AE may be exposed in portions overlapping the openings OP, and may be in contact with the first to third light emitting layers EL1, EL2, and EL3 in portions overlapping the openings OP. Edge of the anode electrodes AE that do not overlap the openings OP may be covered by the pixel defining layer PDL.

In a fabricating process of the display device 10, the anode auxiliary electrode AXL and the second conductive layer AEb may be formed in different processes. Accordingly, a boundary surface may be formed on one surface where the anode auxiliary electrode AXL and the anode electrode AE face each other. It can be seen that the anode auxiliary electrode AXL and the anode electrode AE are formed in different processes through the boundary surface formed on one surface where the anode auxiliary electrode AXL and the anode electrode AE face each other in the display device 10 according to an embodiment. The fabricating process will be described later.

As illustrated in FIG. 6, the anode electrode AE may include a first layer 1a, a second layer 2a, and a third layer 3a that are stacked in the third direction DR3. The first layer 1a may include transparent conductive oxide (TCO). As an example, the first layer 1a may include at least one of indium zinc oxide (IZO) and indium tin oxide (ITO). The second layer 2a may include silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), or mixtures thereof. The third layer 3a may include the same material as the first layer 1a. As an example, the anode electrode AE may have a multilayer structure of ITO/Ag/ITO, but is not limited thereto.

The anode planarization layer APL may be located between the anode auxiliary electrode AXL and the anode electrode AE. The anode planarization layer APL may be in contact with the anode auxiliary electrode AXL and the anode electrode AE, and may be completely surrounded by the anode auxiliary electrode AXL and the anode electrode AE in a portion overlapping the anode contact hole ACTH.

The anode planarization layer APL may be located in the anode contact hole ACTH, and may planarize the step included in the anode auxiliary electrode AXL in a portion overlapping the anode contact hole ACTH.

The display device 10 according to an embodiment may include the anode electrode AE having one surface flat in the first direction DR1 by including the anode planarization layer APL between the anode auxiliary electrode AXL and the anode electrode AE.

The first to third emitting layers EL1, EL2, and EL3 may be located on the anode electrodes AE. The first to third emitting layers EL1, EL2, and EL3 may be located in portions overlapping the emission areas EA and the non-emission area NLA. The first to third emitting layers EL1, EL2, and EL3 may overlap the bank structure BN and the element insulating layer DIL in the third direction DR3.

The first to third light emitting layers EL1, EL2, and EL3 may be in contact with the anode electrodes AE in portions overlapping the openings OP, and may entirely cover the pixel defining layer PDL in a portion overlapping the non-emission area NLA.

Each of the first to third light emitting layers EL1, EL2, and EL3 may be an organic light emitting layer made of an organic material. Each of the first to third light emitting layers EL1, EL2, and EL3 may include any material that is generally used.

The first light emitting layer EL1, the second light emitting layer EL2, and the third light emitting layer EL3 may emit light of different colors. As an example, the first light emitting layer EL1 may emit the red light, the second light emitting layer EL2 may emit the green light, and the third light emitting layer EL3 may emit the blue light, but the present disclosure is not limited thereto.

The first light emitting layer EL1 may be located in a portion overlapping the first emission area EA1, the second light emitting layer EL2 may be located in a portion overlapping the second emission area EA2, and the third light emitting layer EL3 may be located in a portion overlapping the third emission area EA3. The first light emitting layer EL1, the second light emitting layer EL2, and the third light emitting layer EL3 may be spaced apart from each other in a portion overlapping the non-emission area NLA.

In the display device 10 according to an embodiment, the third bank layer BN3 includes the tip, and accordingly, the first light emitting layer EL1, the second light emitting layer EL2, and the third light emitting layer EL3 spaced apart from each other may be formed without using a separate fine metal mask in the fabricating process of the display device 10. In other words, the first light emitting layer EL1, the second light emitting layer EL2, and the third light emitting layer EL3 may be formed by a photo pattern process.

The display device 10 according to an embodiment includes the anode planarization layer APL between the anode auxiliary electrode AXL and the anode electrode AE, and accordingly, each of the first light emitting layer EL1, the second light emitting layer EL2, and the third light emitting layer EL3 may include one surface fact in the first direction DR1 in a portion overlapping the anode contact hole ACTH.

The cathode electrodes CE may be located on the first to third light emitting layers EL1, EL2, and EL3. The cathode electrodes CE may be located in portions overlapping the emission areas EA and the non-emission area NLA. The cathode electrodes CE may entirely cover the first to third light emitting layers EL1, EL2, and EL3.

The cathode electrode CE may be in contact with the bank structure BN, and for this reason, may be electrically connected to the bank structure BN. Specifically, the cathode electrode CE may be in contact with the tip of the third bank layer BN3.

The cathode electrodes CE may emit the light generated in the first to third light emitting structures EL1, EL2, and EL3 by including a transparent conductive material. As an example, the cathode electrode CE may include a layer made of a material having a small work function, such as Li, Ca, LiF/Ca, LiF/Al, Al, Mg, Ag, Pt, Pd, Ni, Au, Nd, Ir, Cr, BaF, Ba, or compounds or mixtures thereof (e.g., a mixture of Ag and Mg, etc.). The cathode electrode CE may further include a transparent metal oxide layer disposed on the layer made of the material having the small work function.

In an embodiment, the cathode electrode CE located in a portion overlapping the first emission area EA1, the cathode electrode CE located in a portion overlapping the second emission area EA2, and the cathode electrode CE located in a portion overlapping the third emission area EA3 may be spaced apart from each other. The cathode electrodes CE located in the first to third emission areas EA1, EA2, and EA3 so as to be spaced apart from each other may be electrically connected to each other through the bank structure BN. Specifically, the cathode electrodes CE located in the first to third emission areas EA1, EA2, and EA3 so as to be spaced apart from each other may be in contact with the third bank layers BN3 located in the first to third emission areas EA1, EA2, and EA3 so as to be spaced apart from each other, and may be electrically connected to each other through the second bank layers BN2 and the first bank layer BN1 electrically connected to the third bank layers BN3.

In the display device 10 according to an embodiment, the third bank layer BN3 includes the tip, and accordingly, the cathode electrodes CE located in the first to third emission areas EA1, EA2, and EA3 so as to be spaced apart from each other may be formed without a separate fine metal mask. In other words, the cathode electrodes CE may be formed by a photo pattern process.

The auxiliary electrodes AX may be located on the cathode electrodes CE. The auxiliary electrodes AX may be located in portions overlapping the emission areas EA and the non-emission area NLA. The auxiliary electrodes AX may entirely cover the cathode electrodes CE. The auxiliary electrodes AX may assist the cathode electrodes CE to be electrically connected to each other.

The auxiliary electrode AX may include transparent conductive oxide (TCO). As an example, the auxiliary electrode AX may include at least one of indium zinc oxide (IZO) and indium tin oxide (ITO).

In an embodiment, the auxiliary electrode AX located in a portion overlapping the first emission area EA1, the auxiliary electrode AX located in a portion overlapping the second emission area EA2, and the auxiliary electrode AX located in a portion overlapping the third emission area EA3 may be spaced apart from each other. The auxiliary electrodes AX located in the first to third emission areas EA1, EA2, and EA3 so as to be spaced apart from each other may be electrically connected to each other through the bank structure BN. Specifically, the auxiliary electrodes AX located in the first to third emission areas EA1, EA2, and EA3 so as to be spaced apart from each other may be in contact with the third bank layers BN3 located in the first to third emission areas EA1, EA2, and EA3 so as to be spaced apart from each other, and may be electrically connected to each other through the second bank layers BN2 and the first bank layer BN1 electrically connected to the third bank layers BN3.

The auxiliary electrode AX may be spaced apart from the first bank layer BN1 in the third direction DR3 in a portion overlapping the non-emission area NLA.

The element inorganic layer IO may be located on the light emitting element ED. The element inorganic layer IO may completely cover the light emitting element ED, and may prevent oxygen or moisture from permeating into the light emitting element ED.

The element inorganic layer IO may include an inorganic insulating material. As an example, the element inorganic layer IO may include any one of silicon nitride, silicon oxide, and silicon oxynitride.

The element inorganic layer IO may include a first element inorganic layer IO1, a second element inorganic layer IO2, and a third element inorganic layer IO3. The first element inorganic layer IO1 may be disposed on the first light emitting element ED1 in the first emission area EA1, the second element inorganic layer IO2 may be disposed on the second light emitting element ED2 in the second emission area EA2, and the third element inorganic layer IO3 may be disposed on the third light emitting element ED3 in the third emission area EA3. The first element inorganic layer IO1, the second element inorganic layer IO2, and the third element inorganic layer IO3 may be spaced apart from each other in a portion overlapping the non-emission area NLA.

It has been illustrated in FIG. 5 that the first element inorganic layer IO1, the second element inorganic layer IO2, and the third element inorganic layer IO3 are formed at a same layer, but in the fabricating process of the display device 10, the first element inorganic layer IO1 may be formed after the first light emitting element ED1 is formed, the second element inorganic layer IO2 may be formed after the second light emitting element ED2 is formed, and the third element inorganic layer IO3 may be formed after the third light emitting element ED3 is formed.

The thin film encapsulation layer TFEL may be located on the display element layer EML. The thin film encapsulation layer TFEL may include an organic encapsulation layer TFE1 and an inorganic encapsulation layer TFE3.

The organic encapsulation layer TFE1 according to an embodiment may be located on the element inorganic layer IO. As an example, the organic encapsulation layer TFE1 may be in entire contact with and entirely cover the first element inorganic layer IO1, the second element inorganic layer IO2, and the third element inorganic layer IO3.

The organic encapsulation layer TFE1 may planarize a step formed along a profile of an underlying structure. The organic encapsulation layer TFE1 may fill a spaced portion between the auxiliary electrode AX and the first bank layer BN1 in a portion overlapping the non-emission area NLA.

The organic encapsulation layer TFE1 may include a polymer-based material. As an example, the organic encapsulation layer TFE1 may include an acrylic resin, a silicone resin, an epoxy-based resin, a silicone acrylic resin, polyimide, polyethylene, and the like.

The inorganic encapsulation layer TFE3 may be located on the organic encapsulation layer TFE1. The inorganic encapsulation layer TFE3 may protect an underlying structure so that moisture and oxygen do not permeate into the underlying structure. The inorganic encapsulation layer TFE3 may also be omitted according to embodiments.

The inorganic encapsulation layer TFE3 may include an inorganic insulating material. As an example, the inorganic encapsulation layer TFE3 may include any one of silicon nitride, silicon oxide, and silicon oxynitride.

As illustrated in FIG. 6, the bank structure BN may have an asymmetrical structure in a portion facing the anode contact hole ACTH and a portion opposing the portion facing the anode contact hole ACTH.

As an example, side surfaces of the first bank layer BN1, the second bank layer BN2, and the third bank layer BN3 located in the portion facing the anode contact hole ACTH may be located on the same line. The phrase “located on the same line” described above may have the same meaning as being aligned or extending.

The side surfaces of the first bank layer BN1, the second bank layer BN2, and the third bank layer BN3 located in the portion facing the anode contact hole ACTH may be located by the same process in the fabricating process of the display device 10. The fabricating process will be described later.

As an example, in the portion opposing the portion facing the anode contact hole ACTH, the third bank layer BN3 may protrude more than the side surface 2c of the second bank layer BN2 toward the first direction DR1. An overlapping description is omitted.

In an embodiment, the cathode electrode CE may be located on the tip of the third bank layer BN3 so as to be in contact with the tip of the third bank layer BN3. In addition, the auxiliary electrode AX may be in contact with the tip of the third bank layer BN3, and may extend and be in contact with the second bank layer BN2. However, the present disclosure is not limited thereto, and the auxiliary electrode AX may not be in contact with the second bank layer BN2.

In an embodiment, an area where the auxiliary electrode AX is in contact with the bank structure BN may be greater than an area where the cathode electrode CE is in contact with the bank structure BN.

In an embodiment, the first bank layer BN1, the second bank layer BN2, and the third bank layer BN3 may be spaced apart from the anode planarization layer APL with the element insulating layer DIL. The element insulating layer DIL may be disposed between the first bank layer BN1, the second bank layer BN2, and the third bank layer BN3 and the anode planarization layer APL. In addition, the first bank layer BN1, the second bank layer BN2, and the third bank layer BN3 may surround the anode planarization layer APL.

In an embodiment, the anode auxiliary electrode AXL may include an upper surface q1. The upper surface q1 may be one surface facing the first layer 1a of the anode electrode AE.

In an embodiment, the anode planarization layer APL may include an upper surface p1. The upper surface p1 may be one surface facing the anode electrode AE. The upper surface p1 of the anode planarization layer APL will be described later.

In an embodiment, the first layer 1a of the anode electrode AE may include a portion in contact with the upper surface p1 of the anode planarization layer APL and a portion in contact with the upper surface q1 of the anode auxiliary electrode AXL.

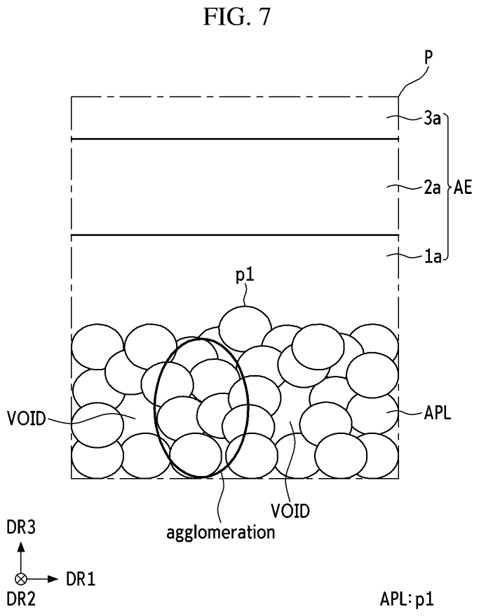

FIG. 7 is an enlarged cross-sectional view of area ‘P’ in FIG. 6.

Referring to FIG. 7 in addition to FIGS. 1 to 6, the anode planarization layer APL according to an embodiment may include a conductive nano paste. As an example, the conductive nano paste may refer to nanometer-sized particles having conductivity. In general, the conductive nano paste may have excellent electrical conductivity, adhesiveness, and processability.

In an embodiment, the anode planarization layer APL may electrically connect the anode electrode AE and the anode auxiliary electrode AXL to each other by including the conductive nano paste.

In an embodiment, the anode planarization layer APL may include silver (Ag) particles having a nanometer size. As an example, each silver (Ag) particle may have a size of 1 nanometer or more and 100 nanometers or less.

In an embodiment, the anode planarization layer APL may have a surface roughness on the upper surface p1 by including the silver (Ag) particles having the nanometer size. As an example, the surface roughness may refer to a degree of a fine ruggedness structure formed on a surface of a metal.

As an example, the surface roughness of the upper surface p1 of the anode planarization layer APL may have a value of 10 nanometers or less. The surface roughness described above may be measured using an atomic force microscope (AFM). The AFM may refer to a measurement method that increases a resolution up to a molecular or atomic level by scanning a surface of a sample through a probe.

In the fabricating process of the display device 10 according to an embodiment, the anode planarization layer APL may be formed through a printing process. For example, a mixture of metal powders having a size of several hundred nanometers to several micrometers and a binder resin may have high viscosity characteristics, and it may thus be difficult to fabricate a high-resolution display device. In addition, when a polymer resin mixture is used, electrical conductivity may decrease because a polymer having low electrical conductivity is mixed between the metal powders.

Accordingly, in the display device 10 according to an embodiment, the anode planarization layer APL may be formed by various printing methods by dispersing the silver (Ag) particles having the nanometer size in an evaporable solvent and performing a process. The fabricating process will be described later.

The anode planarization layer APL according to an embodiment may include agglomerations and voids VOID. The agglomeration may refer to a portion where a plurality of silver (Ag) particles are agglomerated, and the void VOID may refer to an area formed because the silver (Ag) nanoparticles are agglomerated. The void VOID may be a portion that does not include the silver (Ag) particles.

As an example, the agglomerations may be formed because the silver (Ag) nanoparticles are dispersed in a solvent with repulsive force against each other, and the solvent is then evaporated, and accordingly, a distance between the silver (Ag) particles decreases, such that an interaction (e.g., van der Waals force and electrostatic attractive force, etc.) between the silver (Ag) particles becomes strong, in a fabricating process of the anode planarization layer APL. The voids VOID may be formed because the silver (Ag) nanoparticles are uniformly dispersed and the agglomerations are then formed. The number of voids VOID may be plural.

In the display device 10 according to an embodiment, the anode planarization layer APL includes the plurality of voids VOID, and accordingly, it can be seen that a silver (Ag) nano paste dispersed in the solvent is used in the fabricating process of the display device 10.

Referring to FIGS. 6 and 7 again, the display device 10 according to an embodiment may include the anode auxiliary electrode AXL, the anode planarization layer APL, and the first layer 1a, the second layer 2a, and the third layer 3a of the anode electrode AE that are sequentially stacked in a portion overlapping the anode contact hole ACTH. As an example, the display device 10 according to an embodiment may include a structure in which ITO/Ag/ITO/Ag/ITO are sequentially stacked in a portion overlapping the anode contact hole ACTH. Thus, the stacked structure, in one example includes: the anode auxiliary electrode AXL including ITO; the anode planarization layer APL including Ag; the first layer 1a of the anode electrode AE including ITO; the second layer 2a of the anode electrode AE including Ag; and the third layer 3a of the anode electrode AE including ITO. Accordingly, the second connection electrode CNE2 may be connected to the anode electrode AE through the anode auxiliary electrode AXL and the anode planarization layer APL.

The display device 10 according to an embodiment includes the anode planarization layer APL including silver (Ag) between the anode auxiliary electrode AXL and the anode electrode AE, and thus, electrical resistance of the display device 10 may be reduced compared to a structure in which the anode planarization layer APL is not included.

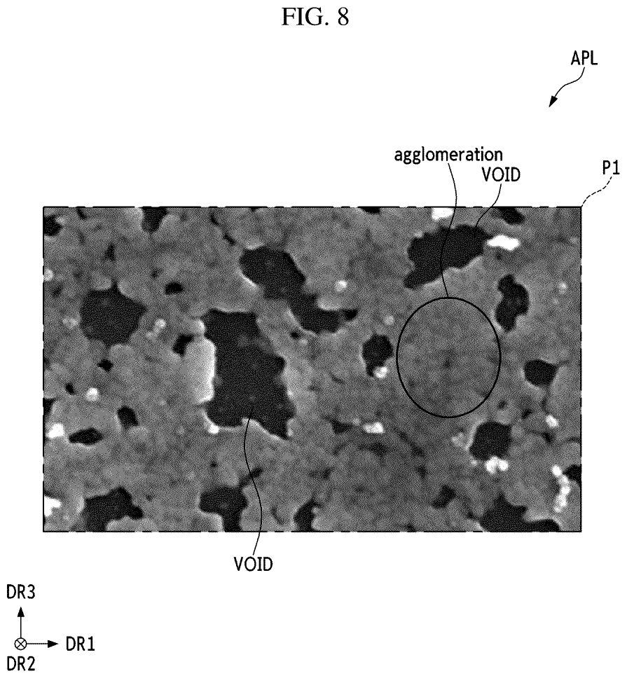

FIG. 8 is an enlarged field emission scanning electron microscope (FE-SEM) plane image of an upper surface of an anode planarization layer in FIG. 6. In an embodiment, a FE-SEM is a field emission scanning electron microscope, and may refer to a device capable of obtaining a high-resolution image.

Referring to FIG. 8 in addition to FIGS. 1 to 7, the anode planarization layer APL may include agglomerations and voids VOID in plan view. As described above, the agglomerations may be formed by the interaction (e.g., van der Waals force, electrostatic attractive force, etc.) between the silver (Ag) particles in the fabricating process, and the voids VOID may be formed as the agglomerations are formed.

In plan view, the anode planarization layer APL may include a plurality of void VOID, and the plurality of void VOID may be spaced apart from each other in plan view.

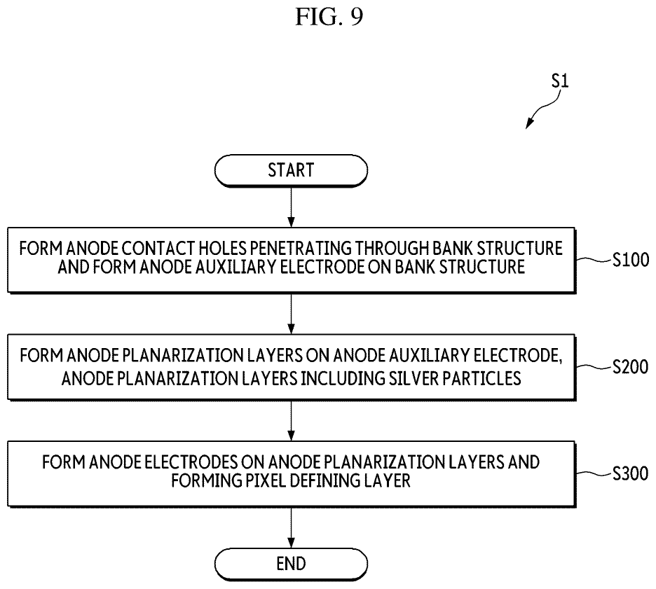

FIG. 9 is a flowchart illustrating a method 900 for fabricating a portion of the display element layer in FIG. 5.

Referring to FIG. 9 in addition to FIGS. 1 to 8, the method S1 for fabricating a portion of the display element layer EML according to an embodiment may include: a block S100 for forming the anode contact holes penetrating through the bank structure and forming the anode auxiliary electrode on the bank structure, a block S200 for forming the anode planarization layers on the anode auxiliary electrode, the anode planarization layers including silver particles, and a block S300 for forming the anode electrodes on the anode planarization layers and forming the pixel defining layer.

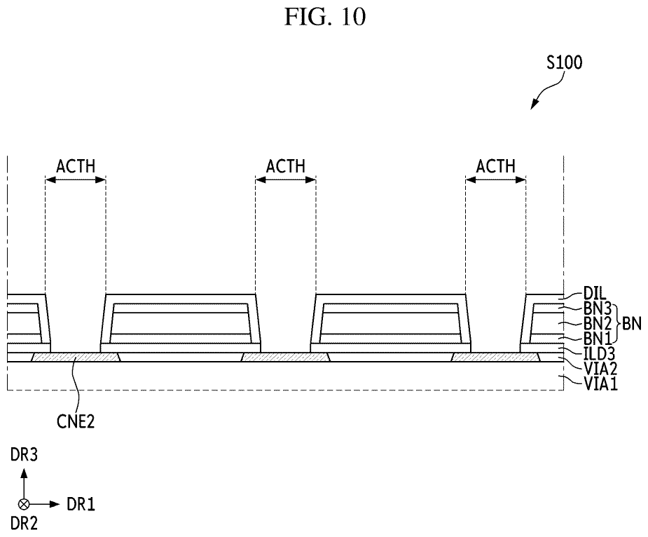

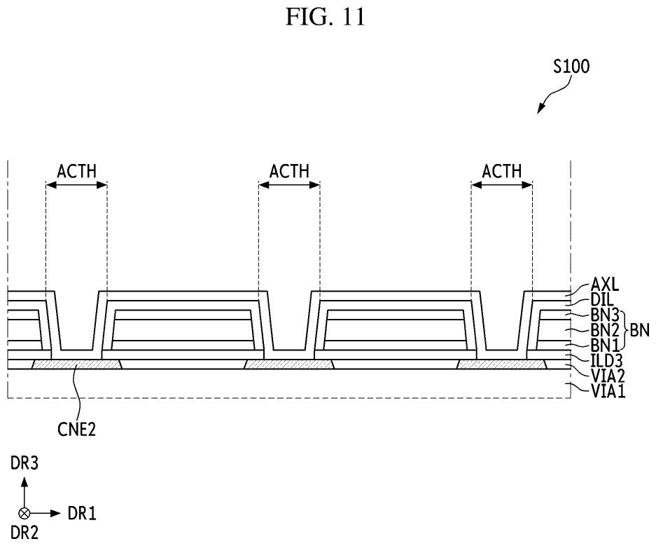

FIGS. 10 and 11 are cross-sectional views for describing the forming of the anode contact holes penetrating through the bank structure and the forming of the anode auxiliary electrode on the bank structure in accordance with block S100 of FIG. 9.

The forming of the anode contact holes penetrating through the bank structure and the forming of the anode auxiliary electrode on the bank structure in accordance with block S100 is described with reference to FIGS. 10 and 11 in addition to FIGS. 1 to 9.

First, a plurality of second connection electrodes CNE2 are formed on the first via layer VIA1, and the second via layer VIA2, the third insulating layer ILD3, and the bank structure BN are entirely formed. The bank structure BN may include the first bank layer BN1, the second bank layer BN2, and the third bank layer BN3 that are sequentially stacked.

In the present process, the second bank layer BN2 and the third bank layer BN3 may include different materials. As an example, the third bank layer BN3 may include a material having higher etching resistance than the second bank layer BN2. An overlapping description is omitted.

Although not illustrated in FIGS. 10 and 11, the thin film transistor layer TFTL including the first via layer VIA1 and the second via layer VIA2 may be located on the substrate SUB, and a detailed structure of the thin film transistor layer TFTL is the same as that illustrated in FIG. 5.

Subsequently, holes penetrating through the bank structure BN and exposing the third insulating layer ILD3 are formed by performing an etching process, and the element insulating layer DIL is entirely formed on the third bank layer BN3. Thereafter, the anode contact holes ACTH penetrating through the element insulating layer DIL and the third insulating layer ILD3 and exposing the second connection electrodes CNE2 are formed by performing an etching process again.

Next, as illustrated in FIG. 11, the anode auxiliary electrode AXL is formed on the element insulating layer DIL. In the present process, the anode auxiliary electrode AXL may be formed through a film forming process (e.g., a sputtering process) of forming at least one of the metal materials described above.

In the present process, the anode auxiliary electrode AXL may be in entirely contact with and entirely cover the second connection electrodes CNE2 exposed in portions overlapping the anode contact holes ACTH, and may extend to cover the element insulating layer DIL. The anode auxiliary electrode AXL may be spaced apart from the bank structure BN by the element insulating layer DIL.

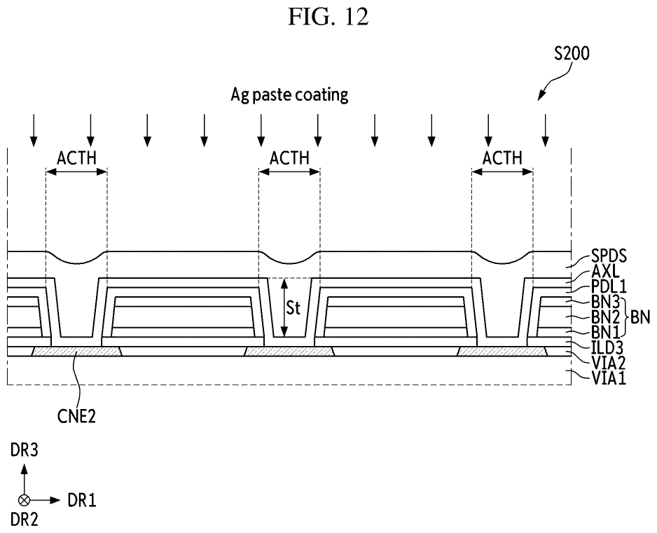

FIGS. 12 to 15 are cross-sectional views for describing the forming of the anode planarization layers on the anode auxiliary electrode according to block S200 of FIG. 9.

The forming of the anode planarization layers on the anode auxiliary electrode according to block S200 is described with reference to FIGS. 12 to 15 in addition to FIGS. 1 to 11.

First, a silver paste solution SPDS is sprayed on the anode auxiliary electrode AXL by performing a silver particle coating method. The silver paste solution SPDS refers to a solution in which a plurality of silver particles having a nanometer size are dispersed in a solvent. The silver paste solution SPDS may further include additives having several functions in addition to the silver particles and the solvent.

As the solvent included in the silver paste solution SPDS, materials having various viscosities may be used depending on a demanded printing method. For example, when tetradecane is used as the solvent, the tetradecane may have a viscosity range of 5 mPa·s to 20 mPa·s, and when decanol is used as the solvent, the decanol may have a viscosity range of 100 Pa·s to 200 Pa·s. However, the present disclosure does not limit a type of the solvent.

As an example, the present process may be performed using an inkjet printing method, a paste coating method, or the like.

For example, the inkjet printing method is a method for spraying the silver paste solution SPDS through a small nozzle, and as an example, the silver paste solution SPDS may be entirely formed on the anode auxiliary electrode AXL by performing an over drop process or may be formed only in portions overlapping the anode contact holes ACTH by performing an align drop process.

For example, when the silver paste solution SPDS is applied by performing the align drop process, a subsequent plasma treatment process may be omitted.

In the present process, the silver paste solution SPDS may be located on the anode auxiliary electrode AXL, and may be formed at a thickness greater than a height of a step St included in the anode auxiliary electrode AXL. Accordingly, the silver paste solution SPDS may planarize the step St included in the anode auxiliary electrode AXL.

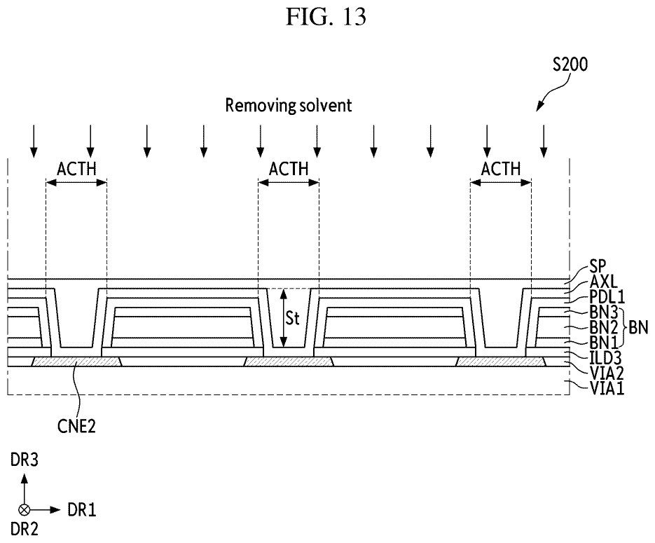

Next, as illustrated in FIG. 13, the solvent is removed through a solvent removing process. As an example, as the solvent removing process, there may be a method for slowly evaporating the solvent at 20 °C or more and 80 °C or less, a method for evaporating the solvent by performing heat treatment at 100 °C or more, a method for removing the solvent in a low-pressure environment of a vacuum chamber, a method for removing the solvent using microwave energy and ultrasonic energy, and the like.

In the present process, both the solvent and impurities may be removed from the silver paste solution SPDS, and only silver particles SP may remain.

In the present process, the silver particles SP may be maintained at the thickness greater than the height of the step St included in the anode auxiliary electrode AXL. Accordingly, the silver particles SP dispersed in the solvent may planarize the step St included in the anode auxiliary electrode AXL.

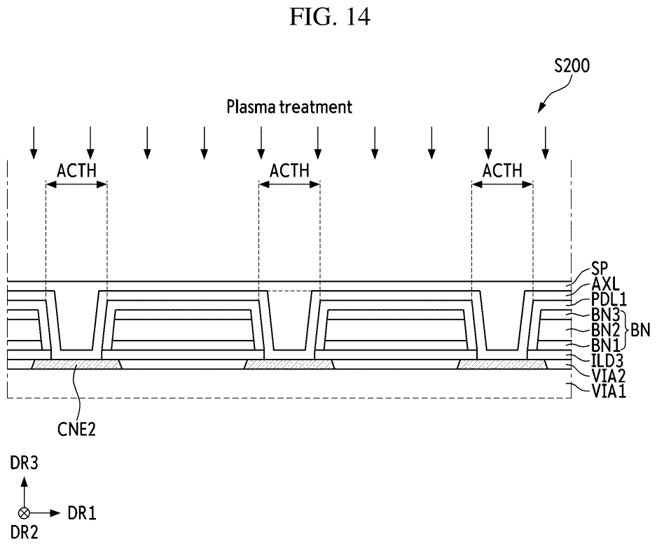

Subsequently, a plasma treatment process is performed as illustrated in FIG. 14. In the present process, at least one of plasma etching (PE), reactive ion etching (RIE), and inductively coupled plasma (ICP) may be used.

In the present process, plasma may include a fluorine-based gas. As an example, in the present process, CHF₃, CH₃F, CH₂F₂, CHF₆, CF₄, C₂F₆, C₃F₆, F₂, or the like, may be used. In the present process, a fluorine (F) gas may be used to perform a radical reaction with silver (Ag).

In the present process, the silver (Ag) nano paste and the fluorine gas may form silver fluoride (AgF) by performing an ion radical reaction. In other words, in the present process, all of the silver particles SP that do not overlap the anode contact holes ACTH and portions of surfaces of the silver particles SP that overlap the anode contact holes ACTH may form silver fluoride (AgF).

In the present process, most of the silver fluoride (AgF) may be dissolved and removed through a cleaning process.

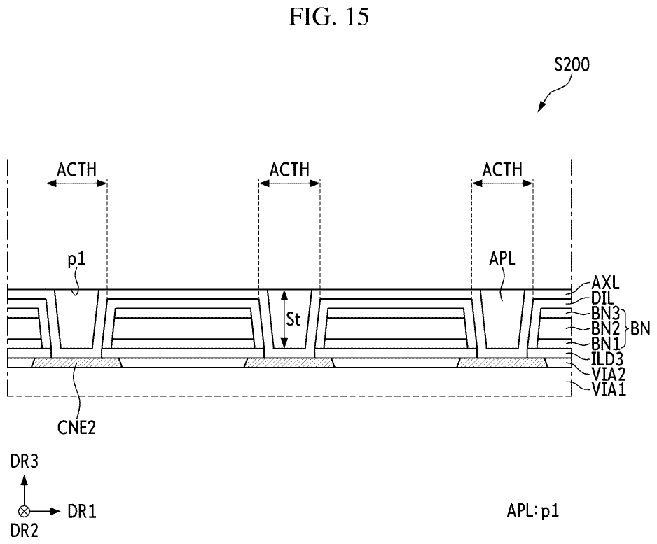

Through the present process, as illustrated in FIG. 15, all of the silver particles SP that do not overlap the anode contact holes ACTH may be removed, and portions of the surfaces of the silver particles SP that overlap the anode contact holes ACTH may be removed.

As a result, the anode planarization layers APL may be formed.

In the present process, the anode planarization layers APL may planarize the steps St included in the anode auxiliary electrode AXL. In addition, the anode planarization layer APL includes a plurality of silver (Ag) particles having a nanometer size, and accordingly, the upper surface p1 of the anode planarization layer APL may have a surface roughness of 10 nanometers or less. An overlapping description is omitted.

In some embodiments, the upper surface p1 of the anode planarization layer APL may include some silver fluoride (AgF).

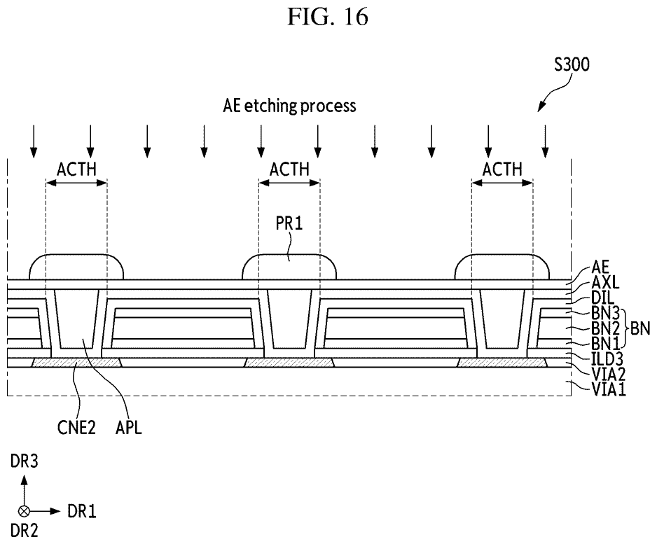

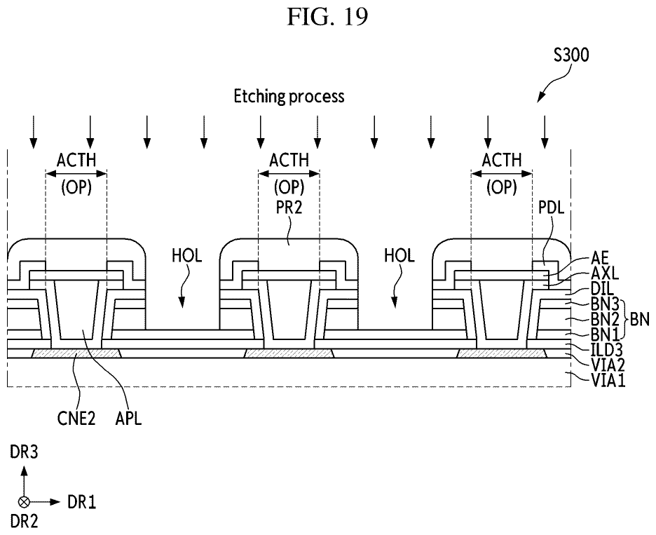

FIGS. 16 to 20 are cross-sectional views for describing the forming of the anode electrodes on the anode planarization layers and forming the pixel defining layer according to block S300 of FIG. 9.

The forming of the anode electrodes on the anode planarization layers and the forming of the pixel defining layer according to block S300 is described with reference to FIGS. 16 to 20 in addition to FIGS. 1 to 15.

First, the anode electrode AE is formed on the anode auxiliary electrode AXL and the anode planarization layers APL.

In the present process, the anode electrode AE may be formed through a film forming process (e.g., a sputtering process) of forming at least one of the metal materials described above.

Subsequently, a photoresist PR1 is formed on the anode electrode AE, and an anode etching process is performed. In the present process, a plurality of photoresists PR1 may be formed, and may be located in portions overlapping the anode contact holes ACTH. As an example, the anode etching process may be performed through at least one of a dry etching process or a wet etching process.

As an example, the dry etching process may be performed through a reactive ion etching (RIE) process using a reaction gas such as CHF₃, CH₃F, CH₂F₂, CHF₆, CF₄, C₂F₆, or C₃F₆, and a sputtering gas such as Ar or O₂/Ar. In this case, an inductively coupled plasma (ICP) source or a capacitively coupled plasma (CCP) source may be used as a plasma source.

As an example, the wet etching process may be performed using a liquid chemical solution such as a diluted hydrofluoric acid solution, a nitric acid solution, a tetramethylammonium hydroxide solution, or a potassium hydroxide solution.

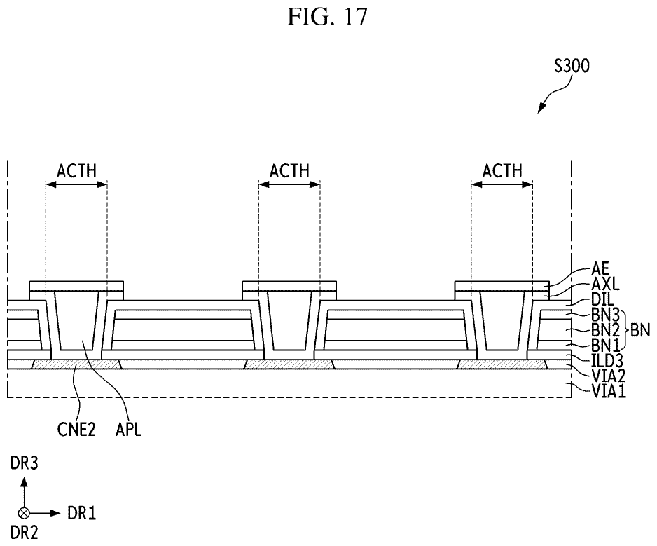

As illustrated in FIG. 17, the anode auxiliary electrode AXL and the anode electrode AE that do not overlap the photoresists PR1 may be removed through the present process. In the present process, the anode planarization layers APL may be completely surrounded by the anode auxiliary electrodes AXL and the anode electrodes AE.

Although not illustrated in FIG. 17, the photoresists PR1 may be removed through an ashing process.

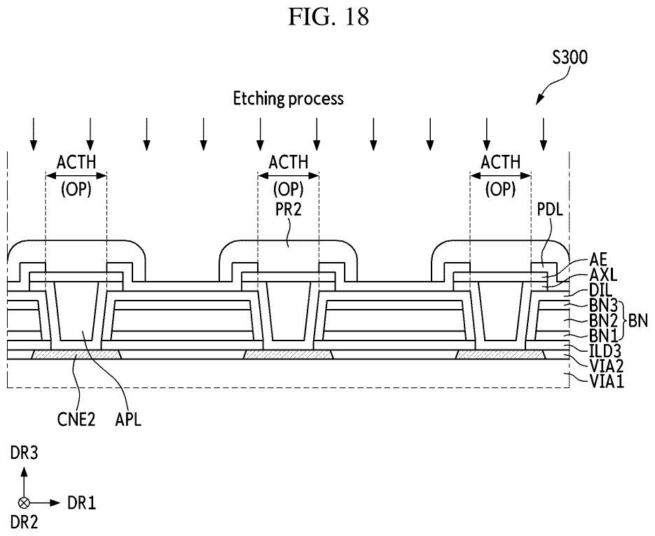

Next, as illustrated in FIG. 18, the pixel defining layer PDL defining the openings OP is formed on the anode electrodes AE and the element insulating layer DIL. In the present process, the anode electrodes AE may be exposed in portions that overlap the openings OP. In the present process, the pixel defining layer PDL may be located on the anode electrodes AE and the element insulating layer DIL in portions that do not overlap the openings OP.

Subsequently, a photoresist PR2 is formed on the pixel defining layer PDL, and an etching process is performed. In the present process, a plurality of photoresists PR2 may be formed, and may be located in portions overlapping the anode contact holes ACTH. As an example, a dry etching process and a wet etching process may be alternately performed as the etching process. An overlapping description is omitted.

First, the pixel defining layer PDL, the element insulating layer DIL, the second bank layer BN2, and the third bank layer BN3 that do not overlap the photoresists PR2 are removed by performing the dry etching process. In the present process, the pixel defining layer PDL, the element insulating layer DIL, the second bank layer BN2, and the third bank layer BN3 that do not overlap the photoresists PR2 may be removed at once, and for this reason, holes HOL may be formed. The holes HOL may be formed in portions that do not overlap the anode contact holes ACTH, and a side surface of the pixel defining layer PDL, a side surface of the element insulating layer DIL, a side surface of the second bank layer BN2, and a side surface of the third bank layer BN3 that face the hole HOL may be located on the same line. In other words, in the present process, the pixel defining layer PDL, the element insulating layer DIL, the second bank layer BN2, and the third bank layer BN3 that do not overlap the photoresists PR2 may be isotropically removed.

In the present process, the first bank layer BN1 overlapping the holes HOL may be exposed.

Subsequently, the wet etching process is performed. In the present process, the second bank layer BN2 and the third bank layer BN3 including different metal materials may have different etching selectivities. Specifically, in the same etching process, the third bank layer BN3 may have higher etching resistance than the second bank layer BN2. In other words, in the same etching process, the second bank layer BN2 may include a material having a higher etching rate than the third bank layer BN3.

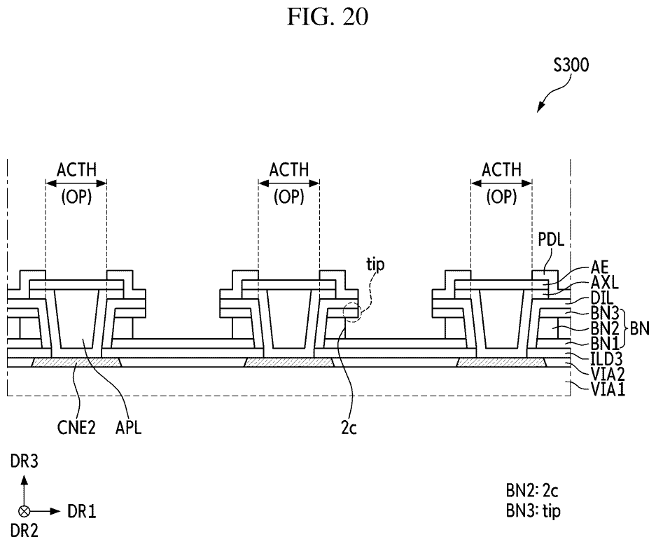

Accordingly, through the present process, as illustrated in FIG. 20, the third bank layer BN3 may include the tip protruding more than the side surface 2c of the second bank layer BN2 in the first direction DR1. The element insulating layer DIL and the pixel defining layer PDL may overlap the tip of the third bank layer BN3 in the third direction DR3. An overlapping description is omitted.

Although not illustrated in FIG. 20, the photoresists PR2 may be removed through an ashing process.

Consequently, the bank structure BN, the element insulating layers DIL, the anode auxiliary electrodes AXL, the anode planarization layers APL, the anode electrodes AE, and the pixel defining layer PDL illustrated in FIG. 5 may be formed.

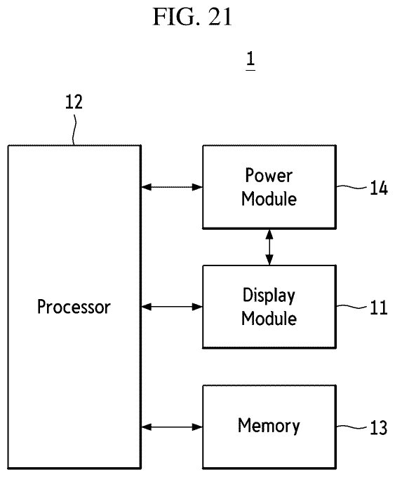

FIG. 21 is a block diagram of an electronic device according to an embodiment.

Referring to FIG. 21 in addition to FIGS. 1 to 20, the display device 10 according to an embodiment may be applied to various electronic devices 1. The electronic device 1 according to an embodiment may include the display device 10 described above, and may further include modules or devices having other additional functions in addition to the display device 10.

The electronic device 1 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for an operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device and a power conversion module converting power supplied by the power supply module to generate power required for an operation of the electronic device 1.

At least one of the respective components of the above-described electronic device 1 may be included in the display device according to the above-described embodiments. In addition, some of individual modules functionally included in one module may be included in the display device, and the others of the individual modules may be provided separately from the display device. For example, the display device may include the display module 11, and the processor 12, the memory 13, and the power module 14 may be provided in the form of other devices within the electronic device 1 rather than the display device.

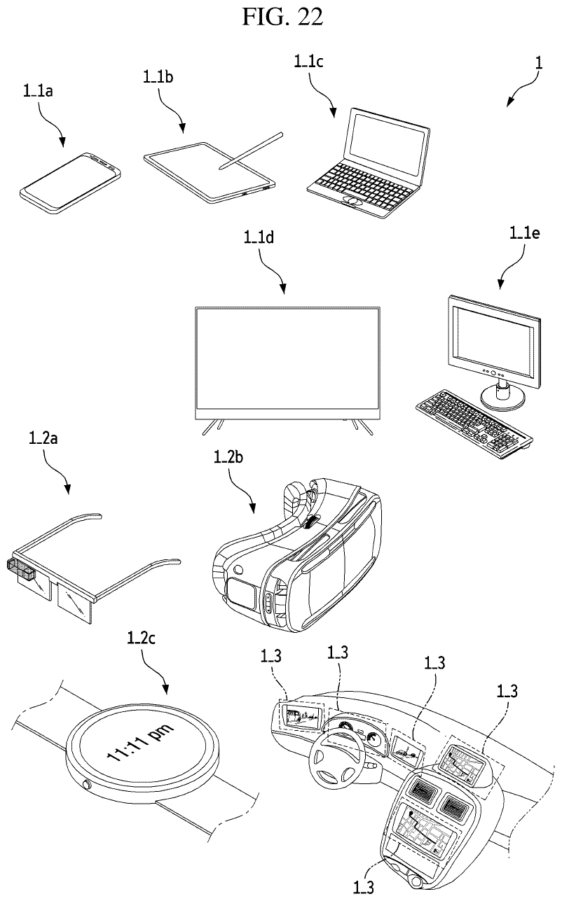

FIG. 22 is schematic views of electronic devices according to various embodiments.

Referring to FIG. 22, various electronic devices 1 to which the display device 10 according to embodiments is applied may include not only image display electronic devices such as a smartphone 1_1a, a tablet PC 1_1b, a laptop computer 1_1c, a television (TV) 1_1d, and a monitor 1_1e for a desktop computer, but also wearable electronic devices including display modules, such as a smart glasses 1_2a, a head mounted display 1_2b, and a smart watch 1_2c, and vehicle electronic devices 1_3 including display modules, such as a center information display (CID) disposed on an instrument board, a center fascia, or a dashboard of a vehicle and a room mirror display.

Although the present display device has been described with reference to the embodiments shown in the drawings, these are merely exemplary, and those skilled in the art will understand that various modifications and equivalent other embodiments are possible therefrom. Therefore, the disclosed subject matter should not be limited to any single embodiment described herein.

Moreover, features of various embodiments of the disclosure may be combined partially or totally. As will be clearly appreciated by those skilled in the art, technically various interactions and operations are possible. Also, various embodiments can be practiced individually or in combination.

What is claimed is:

1. A display device comprising:
a substrate including an emission area and a non-emission area;
a bank structure located on the substrate and having an overhang structure;
an anode contact hole overlapping the emission area and penetrating through the bank structure;
an element insulating layer located on the bank structure and covering a side surface of the bank structure so as to overlap the anode contact hole;
an anode auxiliary electrode located on the element insulating layer;
an anode electrode located on the element insulating layer and the anode auxiliary electrode; and
an anode planarization layer located between the anode auxiliary electrode and the anode electrode, located in the anode contact hole, and including silver,
wherein the anode planarization layer includes a plurality of voids spaced apart from each other.

2. The display device of claim 1, wherein the anode planarization layer further includes an agglomeration located between voids of the plurality of voids, and wherein a plurality of silver particles are agglomerated in the anode planarization layer.

3. The display device of claim 2, wherein each silver particle of the plurality of silver particles included in the anode planarization layer has a size of 1 nanometer or more and 100 nanometers or less.

4. The display device of claim 3, wherein the anode planarization layer includes an upper surface facing the anode electrode, and
the upper surface of the anode planarization layer has a surface roughness of 10 nanometers or less.

5. The display device of claim 4, wherein the anode auxiliary electrode includes an upper surface facing the anode electrode, and
the anode electrode includes a first portion in contact with the upper surface of the anode planarization layer and a second portion in contact with the upper surface of the anode auxiliary electrode.

6. The display device of claim 1, wherein the anode electrode includes a first layer and a third layer each including transparent conductive oxide and a second layer including silver,
the anode planarization layer is in contact with the first layer, and
in a portion overlapping the anode contact hole, the anode auxiliary electrode, the anode planarization layer, and the first layer, the second layer, and the third layer of the anode electrode are sequentially stacked.

7. The display device of claim 6, wherein a stacked structure of the anode auxiliary electrode, the anode planarization layer, and the first layer, the second layer, and the third layer of the anode electrode is made of indium tin oxide (ITO)/Ag/ITO/Ag/ITO.

8. The display device of claim 2, wherein in plan view, the voids are located between a plurality of the agglomerations.

9. The display device of claim 2, wherein the bank structure includes:
a first bank layer;
a second bank layer located on the first bank layer; and
a third bank layer having a tip protruding more than a first side surface of the second bank layer toward the non-emission area, and
in a portion overlapping the anode contact hole, the anode planarization layer penetrates through the first bank layer, the second bank layer, and the third bank layer.

10. The display device of claim 9, further comprising:
a pixel defining layer covering an edge of the anode electrode, in contact with the element insulating layer, and defining an emission opening;
a first light emitting layer located on the anode electrode and entirely covering the pixel defining layer; and
a cathode electrode located on the first light emitting layer,
wherein the cathode electrode is in contact with the tip of the third bank layer.

11. The display device of claim 10, further comprising a connection electrode located between the substrate and the bank structure,
wherein the anode auxiliary electrode is in contact with the connection electrode, and
the anode electrode is electrically connected to the connection electrode by the anode planarization layer and the anode auxiliary electrode.

12. A method for fabricating a display device, comprising:
forming an anode contact hole penetrating through a bank structure and forming an anode auxiliary electrode on the bank structure;
forming an anode planarization layer on the anode auxiliary electrode, the anode planarization layer including silver particles; and
forming an anode electrode on the anode planarization layer and forming a pixel defining layer.

13. The method of claim 12, wherein in the forming of the anode planarization layer on the anode auxiliary electrode,
each silver particle of a plurality of silver particles included in the anode planarization layer has a size of 1 nanometer or more and 100 nanometers or less, and
a process for the forming of the anode planarization layer includes:
a process of coating a solution in which the plurality of silver particles are dispersed in a solvent; and
a process of removing the solvent.

14. The method of claim 13, wherein the process for the forming of the anode planarization layer further includes:
a process of plasma treatment that includes treatment with a fluorine-based gas.

15. The method of claim 12, wherein
the bank structure includes a reverse tapered shape,
the bank structure includes a first bank layer, a second bank layer, and a third bank layer,
the second bank layer includes aluminum, and
the third bank layer includes titanium.

16. An electronic device, comprising:
at least one display device including a substrate, the substrate comprising an emission area and a non-emission area; and
at least one of a display module, a processor, a memory, or a power module connected to the at least one display device,
wherein the at least one display device includes:
a bank structure located on the substrate and having an overhang structure;
an anode contact hole overlapping the emission area and penetrating through the bank structure;
an element insulating layer located on the bank structure and covering a side surface of the bank structure so as to overlap the anode contact hole;
an anode auxiliary electrode located on the element insulating layer;
an anode electrode located on the element insulating layer and the anode auxiliary electrode; and
an anode planarization layer located between the anode auxiliary electrode and the anode electrode, located in the anode contact hole, and including silver, and
the anode planarization layer includes a plurality of voids spaced apart from each other.

17. The electronic device of claim 16, wherein the anode planarization layer further includes an agglomeration located between voids of the plurality of voids, and wherein a plurality of silver particles are agglomerated in the anode planarization layer.

18. The electronic device of claim 17, wherein each silver particle of the plurality of silver particles included in the anode planarization layer has a size of 1 nanometer or more and 100 nanometers or less.

19. The electronic device of claim 18, wherein the anode planarization layer includes an upper surface facing the anode electrode, and
the upper surface of the anode planarization layer has a surface roughness of 10 nanometers or less.

20. The electronic device of claim 16, wherein the anode electrode includes a first layer and a third layer each including transparent conductive oxide and a second layer including silver,
in a portion overlapping the anode contact hole, the anode auxiliary electrode, the anode planarization layer, and the first layer, the second layer, and the third layer of the anode electrode are sequentially stacked.
